(19) United States
(12) Patent Application Publication
(10) Pub. No.: US 2025/0218848 A1
(43) Pub. Date: Jul. 3, 2025

(54) METHOD OF MANUFACTURING DISPLAY DEVICE

(71) Applicant: Samsung Display Co., LTD., Yongin-si (KR)

(72) Inventors: Jae Gwang UM, Yongin-si (KR); Tae Hee LEE, Yongin-si (KR); Moon Won CHANG, Yongin-si (KR)

(73) Assignee: Samsung Display Co., LTD., Yongin-si (KR)

(21) Appl. No.: 18/760,836

(22) Filed: Jul. 1, 2024

(30) Foreign Application Priority Data
Dec. 28, 2023 (KR) 10-2023-0195515

(51) Int. Cl. H01L 21/683; H01L 25/075; H01L 33/00; H01L 33/50; H01L 33/60; H01L 33/62

(52) U.S. Cl. CPC H01L 21/6835; H01L 25/0753; H10H 20/018; H10H 20/851; H10H 20/856; H10H 20/857; H01L 2221/68318; H01L 2221/68354; H01L 2221/68368; H10H 20/0364

(57) ABSTRACT

In a method of manufacturing a display device, the method includes aligning a metal layer of a transfer substrate and a display substrate to face each other, attaching a light emitting element including a metal protrusion portion bonded to the metal layer to an overcoat layer of the display substrate by moving the transfer substrate relative to the display substrate, and separating the metal protrusion portion from the light emitting element by moving the transfer substrate relative to the display substrate.

### CROSS-REFERENCE TO RELATED APPLICATION(S)

This application claims priority to and benefits of Korean patent application No. 10-2023-0195515 under 35 U.S.C. § 119 (a), filed on Dec. 28, 2023 in the Korean Intellectual Property Office, the entire contents of which are incorporated herein by reference.

### BACKGROUND

### 1. Technical Field

This disclosure relates to a method of manufacturing a display device.

### 2. Description of the Related Art

A display device displays an image by combining lights emitted from multiple light emitting elements. In order to manufacture the display device, a series of processes of manufacturing multiple light emitting elements, transferring the light emitting elements, and then providing the light emitting elements on a display substrate may be performed. Reliability deterioration in the process of transferring the multiple light emitting elements and/or the process of providing the light emitting elements on the display substrate is problematic.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a method of manufacturing a display device, in which reliability is improved.

In accordance with an aspect of the disclosure, there is provided a method of manufacturing a display device. The method may include aligning a metal layer of a transfer substrate and a display substrate to face each other, attaching a light emitting element including a metal protrusion portion bonded to the metal layer to an overcoat layer of the display substrate by moving the transfer substrate relative to the display substrate, and separating the metal protrusion portion from the light emitting element by moving the transfer substrate relative to the display substrate.

In the separating of the metal protrusion portion from the light emitting element, the bonding between the metal protrusion portion and the metal layer may be maintained.

In the separating of the metal protrusion portion from the light emitting element, the attachment between the light emitting element and the overcoat layer may be maintained.

The light emitting element may include a light emitting stack structure including a first semiconductor layer, a second semiconductor layer spaced apart from the first semiconductor layer, and an active layer between the first semiconductor layer and the second semiconductor layer. The light emitting element may further include a first bonding electrode electrically connected to the first semiconductor layer, a second bonding electrode connected to the second semiconductor layer, and an insulative film covering at least a portion of an outer circumferential surface of the light emitting stack structure.

Before the separating of the metal protrusion portion from the light emitting element, the metal protrusion portion may be in a state in which the metal protrusion portion is bonded to the insulative film covering a surface of the light emitting stack structure.

Each of the first bonding electrode and the second bonding electrode may protrude in a direction in which the metal protrusion portion protrudes from the surface of the light emitting stack structure.

The metal protrusion portion may protrude further than the first and second bonding electrodes with respect to the direction in which the metal protrusion portion protrudes.

A bonding force between the metal protrusion portion and the insulative film may be weaker than an adhesive force between the light emitting element and the overcoat layer.

The bonding force between the metal protrusion portion and the insulative film may be weaker than a bonding force between the metal protrusion portion and the metal layer.

The bonding force between the metal protrusion portion and the metal layer may be weaker than the adhesive force between the light emitting element and the overcoat layer.

Each of the first bonding electrode and the second bonding electrode may be spaced apart from the metal protrusion portion.

The method may further include, before the aligning of the metal layer of the transfer substrate and the display substrate to face each other, aligning the metal layer of the transfer substrate and the metal protrusion portion included in the light emitting element formed on a surface of a growth substrate to physically contact each other, bonding the metal protrusion portion and the metal layer to each other, and separating the light emitting element from the growth substrate.

The separating of the light emitting element from the growth substrate may include irradiating first laser onto an area in which the growth substrate and the light emitting element physically contact each other.

The bonding of the metal protrusion portion and the metal layer to each other may include irradiating second laser onto an area in which the metal protrusion portion and the metal layer physically contact each other.

The bonding of the metal protrusion portion and the metal layer to each other may include allowing the metal layer and the metal protrusion portion to form an alloy in an area in which the metal protrusion portion and the metal layer physically contact each other.

In accordance with another aspect of the disclosure, there is provided a method of manufacturing a display device. The method may include aligning a metal layer of a transfer substrate and a display substrate to face each other, attaching a light emitting element including a metal protrusion portion bonded to the metal layer to an overcoat layer of the display substrate by moving the transfer substrate relative to the display substrate, and separating the metal protrusion portion from the metal layer by moving the transfer substrate relative to the display substrate. The light emitting element may include a light emitting stack structure including a first semiconductor layer, a second semiconductor layer spaced apart from the first semiconductor layer, and an active layer between the first semiconductor layer and the second semiconductor layer, a first bonding electrode electrically connected to the first semiconductor layer, and a second bonding electrode electrically connected to the second semiconductor layer. The metal protrusion portion may include at least one of a first metal protrusion portion overlapping with the first bonding electrode and a second metal protrusion portion overlapping with the second bonding electrode.

In the separating of the metal protrusion portion from the metal layer, the attachment between the light emitting element and the overcoat layer may be maintained.

A bonding force between the metal protrusion portion and the metal layer may be weaker than an adhesive force between the light emitting element and the overcoat layer.

The method may further include before the aligning of the metal layer of the transfer substrate and the display substrate to face each other, aligning the metal layer of the transfer substrate and the metal protrusion portion included in the light emitting element formed on a surface of a growth substrate to physically contact each other, bonding the metal protrusion portion and the metal layer to each other, and separating the light emitting element from the growth substrate.

The bonding of the metal protrusion portion and the metal layer to each other may include allowing the metal layer and the metal protrusion portion to form an alloy in an area in which the metal protrusion portion and the metal layer physically contact each other.

### BRIEF DESCRIPTION OF THE DRAWINGS

Example embodiments will now be described more fully hereinafter with reference to the accompanying drawings; however, the disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments of the disclosure.

FIG. 2 is a schematic block diagram illustrating any one sub-pixel among sub-pixels included in the display device shown in FIG. 1.

FIG. 3 is a schematic plan view illustrating a display panel constituting the display device shown in FIG. 1.

FIG. 4 is a schematic sectional view illustrating an embodiment of the display panel shown in FIG. 3.

FIG. 5 is a schematic sectional view illustrating another embodiment of the display panel shown in FIG. 3.

FIG. 6 is a schematic plan view illustrating any one pixel among pixels included in the display panel shown in FIG. 3.

FIGS. 7 and 8 are schematic sectional views illustrating the pixel shown in FIG. 6.

FIG. 9 is a schematic view illustrating a method of manufacturing the display device in accordance with an embodiment of the disclosure.

FIGS. 10 to 16 are schematic views illustrating the method shown in FIG. 9.

FIG. 17 is a schematic view illustrating a method of manufacturing the display device in accordance with another embodiment of the disclosure.

FIGS. 18 to 24 are schematic views illustrating the method shown in FIG. 17.

FIG. 25 is a schematic block diagram illustrating a display system in accordance with an embodiment of the disclosure.

FIGS. 26 to 29 are schematic perspective views illustrating application examples of the display system shown in FIG. 25.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matter of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

As used herein, the singular forms, “a,” “an,” and “the” are intended to include the plural forms as well, unless the context clearly indicates otherwise.

In the specification, when an element is referred to as being “connected” or “coupled” to another element, it can be directly connected or coupled to the another element or be indirectly connected or coupled to the another element with one or more intervening elements interposed therebetween. It will be understood that when a component “comprises,” “has,” or “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that the terms “connected to” or “coupled to” may include a physical or electrical connection or coupling.

The terms “face” and “facing” mean that a first element may directly or indirectly oppose a second element. In a case in which a third element intervenes between the first and second element, the first and second element may be understood as being indirectly opposed to one another, although still facing each other.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

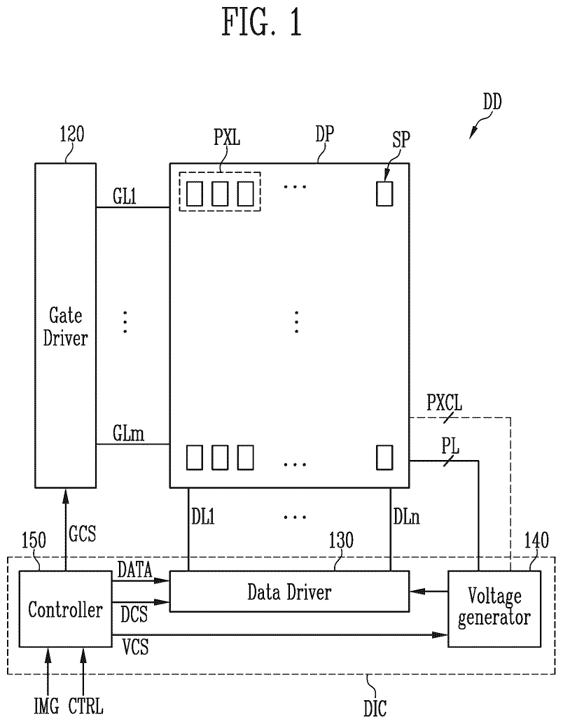

FIG. 1 is a schematic block diagram illustrating a display device in accordance with embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may constitute a pixel PXL. For example, the pixel PXL may include three sub-pixels as shown in FIG. 1. The pixel PXL may emit lights of various colors with various luminances according to a combination of lights emitted from the sub-pixels included in the pixel PXL.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like.

The gate driver 120 may be disposed at one side of the display panel DP. However, embodiments are not limited thereto. For example, the gate driver 120 may be divided into two or more drivers which are physically and/or logically divided, and these drivers may be disposed at a side of the display panel DP and another side of the display panel DP, which may be opposite to the side. As such, in some embodiments, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined or selected reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

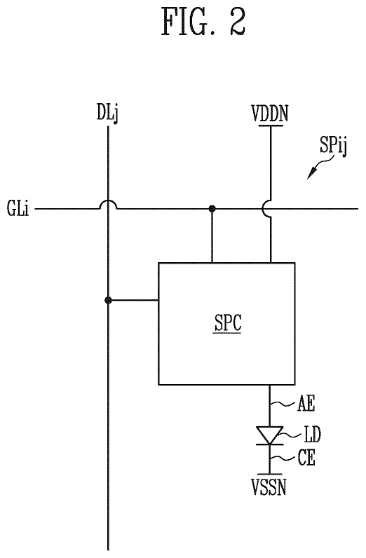

FIG. 2 is a schematic block diagram illustrating any one sub-pixel among the sub-pixels included in the display device shown in FIG. 1. In FIG. 2, a sub-pixel SPij arranged on an ith row (I is an integer which is greater than or equal to 1 and is smaller than or equal to m) and a jth column (j is an integer which is greater than or equal to 1 and is smaller than or equal to n) among the sub-pixels SP shown in FIG. 1 is illustrated.

Referring to FIG. 2, the sub-pixel sPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an ith gate line gLi among the first to mth gate lines GL1 to GLm shown in FIG. 1 and a jth data line DLj among the first to nth data lines DL1 to DLn shown in FIG. 1. In response to a gate signal received through the ith gate line gLi, the sub-pixel circuit SPC may control the light emitting element LD to emit light according to a data signal received through the jth data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, or the like.

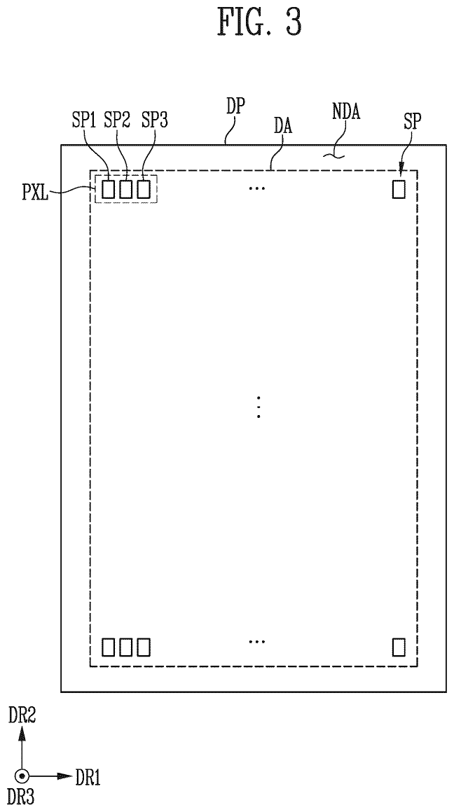

FIG. 3 is a schematic plan view illustrating the display panel constituting the display device shown in FIG. 1.

Referring to FIG. 3, a display panel DP may include a display area DA and a non-display area NDA. The display panel DP may display an image through the display area DA. The non-display area NDA may be disposed at the periphery of the display area DA.

The display panel DP may include sub-pixels SP disposed in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute one pixel PXL. In FIG. 3, it is illustrated that the pixel PXL includes three sub-pixels SP1, SP2, and SP3. However, embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and simple description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1, SP2, and SP3 may include at least one light emitting element configured to generate light. In embodiments, light emitting elements of the first to third sub-pixels SP1, SP2, and SP3 may generate light of a same color. For example, the light emitting elements of the first to third sub-pixels SP1, SP2, and SP3 may generate light of a blue color. In other embodiments, the light emitting elements of the first to third sub-pixels SP1, SP2, and SP3 may generate lights of different colors. For example, the light emitting elements of the first to third sub-pixels SP1, SP2, and SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 130, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into one integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, or an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

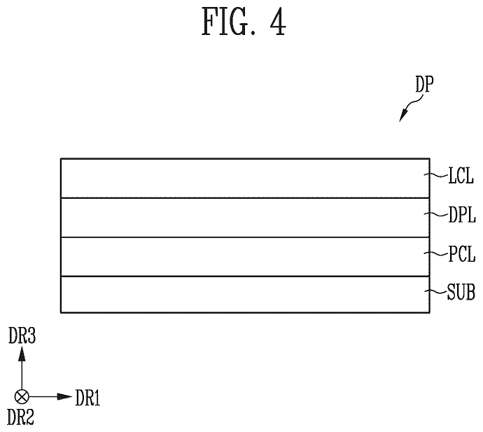

FIG. 4 is a schematic sectional view illustrating an embodiment of the display panel shown in FIG. 3.

Referring to FIG. 4, a display panel DP may include a base substrate SUB, a pixel circuit layer PCL, a display panel layer DPL, and a light conversion layer LCL, which may be stacked on each other in a third direction DR3 intersecting the first and second directions DR1 and DR2 of the base substrate SUB.

The base substrate SUB may be made of an insulative material such as glass or resin. For example, the base substrate SUB may include a glass substrate. In another example, the base substrate SUB may include polyimide (PI) substrate. In still another example, the base substrate SUB may include a silicon wafer substrate formed using a semiconductor process.

In embodiments, the base substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the base substrate SUB. The pixel circuit layer PCL may include insulating layers, and semiconductor patterns and conductive patterns, which may be disposed between the insulating layers. The conductive patterns of the pixel circuit layer PCL may serve as circuit elements, lines, and the like.

The circuit elements of the pixel circuit layer PCL may include the sub-pixel circuit (SPC shown in FIG. 2) of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are for driving the display panel layer DPL.

The display panel layer DPL may be disposed on the pixel circuit layer PCL. The display panel layer DPL may include light emitting elements of the sub-pixels SP.

The light conversion layer LCL may be disposed on the display panel layer DPL. The light conversion layer LCL may include light conversion patterns having color conversion particles and/or light scattering particles. For example, color conversion particles may include quantum dots. The quantum dots may change a wavelength (or color) of light emitted from the display panel layer DPL. In embodiments, the light conversion patterns may be omitted.

The light conversion layer LCL may further include a color filter layer including color filters. The color filter may allow light having a specific wavelength (or specific color) to be selectively transmitted through the color filter. In embodiments, the color filter layer may be omitted.

A window for protecting an exposed surface (or top surface) of the display panel DP may be provided on the light conversion layer LCL. The window may protect the display panel DP from external impact. The window may be bonded to the light conversion layer LCL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

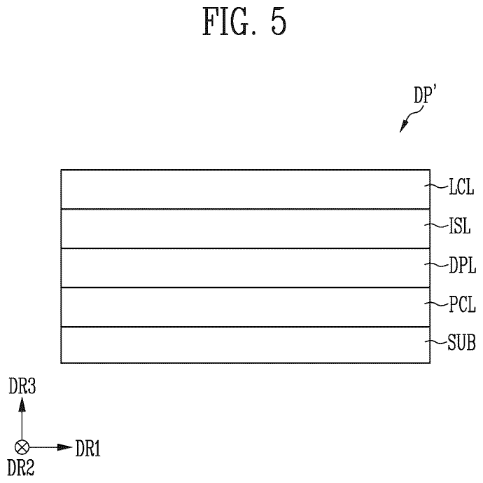

FIG. 5 is a schematic sectional view illustrating another embodiment of the display panel shown in FIG. 3.

Referring to FIG. 5, a display panel DP′ may include a base substrate SUB, a pixel circuit layer PCL, a display panel layer DPL, an input sensing layer ISL, and a light conversion layer LCL. The base substrate SUB, the pixel circuit layer PCL, the display panel layer DPL, and the light conversion layer LCL may be configured substantially identical or similar to the base substrate SUB, the pixel circuit layer PCL, the display panel layer DPL, and the light conversion layer LCL, which have been described with reference to FIG. 4, respectively. Therefore, redundant description will be omitted.

The input sensing layer ISL may sense an input of a user with respect to a top surface (or display surface) of the display panel DP′. The input sensing layer ISL may include components suitable for sensing an external object such as a hand of the user or a pen. For example, the input sensing layer ISL may include touch electrodes.

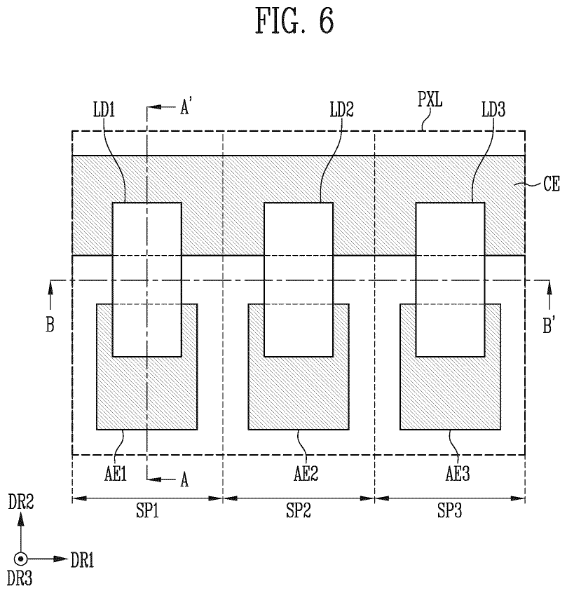

FIG. 6 is a schematic plan view illustrating any one pixel among the pixels included in the display panel shown in FIG. 3.

Referring to FIG. 6, a pixel PXL may include first to third sub-pixels SP1, SP2, and SP3. The first to third sub-pixels SP1, SP2, and SP3 may be arranged in the first direction DR1. However, the arrangement of the first to third sub-pixels SP1, SP2, and SP3 included in the pixel PXL is not limited thereto, and may be variously changed in some embodiments. For example, the first to third sub-pixels SP1, SP2, and SP3 may be arranged in zigzag.

First to third anode electrodes AE1, AE2, and AE3 may be disposed in the first to third sub-pixels SP1, SP2, and SP3, respectively. The first anode electrode AE1 may be provided as an anode electrode (AE shown in FIG. 2) connected to a sub-pixel circuit (SPC shown in FIG. 2) of the first sub-pixel SP1. The second anode electrode AE2 may be provided as an anode electrode (AE shown in FIG. 2) connected to a sub-pixel circuit (SPC shown in FIG. 2) of the second sub-pixel SP2. The third anode electrode AE3 may be provided as an anode electrode (AE shown in FIG. 2) connected to a sub-pixel circuit (SPC shown in FIG. 2) of the third sub-pixel SP3.

A cathode electrode CE may be spaced apart from the first to third anode electrodes AE1, AE2, and AE3. The cathode electrode CE and the first to third anode electrodes AE1, AE2, and AE3 may be disposed at a same height. The cathode electrode CE may be spaced apart from the first to third anode electrodes AE1, AE2, and AE3 in the second direction DR2. In embodiments, the cathode electrode CE may extend in the first direction DR1, to serve as a cathode electrode for the pixel PXL and other pixels adjacent to the pixel PXL. Although not shown in the drawing, the cathode electrode CE may extend in the second direction DR2 in addition to the first direction DR1, to serve as a cathode electrode for all the sub-pixels SP shown in FIG. 3. As such, the cathode electrode CE may have various shapes.

First to third light emitting elements LD1, LD2, and LD3 may be disposed on the first to third anode electrodes AE1, AE2, and AE3 and the cathode electrode CE. The first light emitting element LD1 may be electrically connected to first anode electrode AE1 and the cathode electrode CE. The first light emitting element LD1 may be provided as a light emitting element (LD shown in FIG. 2) connected to the sub-pixel circuit (SPC shown in FIG. 2) of the first sub-pixel SP1. The second light emitting element LD2 may be electrically connected to the second anode electrode AE2 and the cathode electrode CE. The second light emitting element LD2 may be provided as a light emitting element (LD shown in FIG. 2) connected to the sub-pixel circuit (SPC shown in FIG. 2) of the second sub-pixel SP2. The third light emitting element LD3 may be electrically connected to the third anode electrode AE3 and the cathode electrode CE. The third light emitting element LD3 may be provided as a light emitting element (LD shown in FIG. 2) connected to the sub-pixel circuit (SPC shown in FIG. 2) of the third pixel SP3.

The first light emitting element LD1, the second light emitting element LD2, and the third light emitting element LD3 may be inorganic light emitting diodes including an inorganic light emitting material. However, embodiments are not limited thereto. For example, the first light emitting element LD1, the second light emitting element LD2, and the third light emitting element LD3 may be organic light emitting diodes including an organic light emitting material.

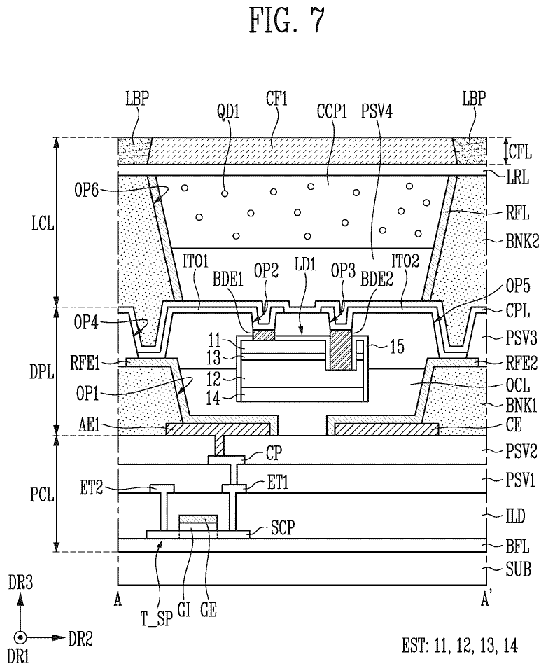

FIG. 7 is a schematic sectional view taken along line A-A′ shown in FIG. 6.

Referring to FIGS. 6 and 7, a pixel circuit layer PCL, a display panel layer DPL, and a light conversion layer LCL may be sequentially disposed on a base substrate SUB.

The pixel circuit layer PCL may include insulating layers, semiconductor patterns, and conductive patterns, which may be stacked on each other on the base substrate SUB. The insulating layers may include a buffer layer BFL, one or more interlayer insulating layers ILD, and one or more passivation layers PSV1, PSV2, and PSV3. The semiconductor patterns and the conductive patterns may be located between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit (SPC shown in FIG. 2) of each of the first to third sub-pixels SP1, SP2, and SP3 may include transistors and one or more capacitors. The semiconductor patterns and the conductive patterns of the pixel circuit layer PCL may serve as the transistors and the capacitors of the sub-pixel circuit SPC. In addition, the conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on the base substrate SUB. The buffer layer BFL may prevent an impurity from being diffused into the semiconductor patterns and the conductive patterns, which are included in the pixel circuit layer PCL. The buffer layer BFL may include an inorganic insulating material. For example, the buffer layer BFL may include silicon nitride, silicon oxide, silicon oxynitride, and/or aluminum oxide.

A transistor T_SP may be disposed on the buffer layer BFL. The transistor T_SP may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode.

The semiconductor pattern SCP may be disposed on the buffer layer BFL. The semiconductor pattern SCP may include a first contact region connected to the first terminal ET1 and a second contact region connected to the second terminal ET2. A region between the first contact region and the second contact region may be a channel region. The channel region may overlap with the gate electrode GE of the transistor T_SP. The channel region is a semiconductor pattern substantially undoped with an impurity. Each of the first contact region and the second contact region is a semiconductor pattern doped with the impurity, and may be a region having a relatively high conductivity. The semiconductor pattern SCP may include, for example, at least one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may include an inorganic insulating material and/or an organic insulating material. For example, each of the interlayer insulating layers ILD may independently include silicon nitride, silicon oxide, silicon oxynitride, and/or aluminum oxide.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers required in the conductive patterns and/or the semiconductor patterns increases, the number of interlayer insulating layers ILD may increase.

The gate electrode GE may be disposed on the gate insulating layer GI. The gate electrode GE may overlap with the channel region of the semiconductor pattern SCP.

The first and second terminals ET1 and ET2 may be disposed on the interlayer insulating layers ILD. The first and second terminals ET1 and ET2 may be connected to the semiconductor pattern SCP through contact holes penetrating the interlayer insulating layers ILD. The first and second terminals ET1 and ET2 may be connected to the first and second contact regions of the semiconductor pattern SCP, respectively.

A first passivation layer PSV1 may be disposed on the interlayer insulating layers ILD. The passivation layer may be designated as a protective layer or a via layer. The first passivation layer PSV1 may protect components disposed under the first passivation layer PSV1, and provide a flat top surface.

A connection pattern CP may be disposed on the first passivation layer PSV1. The connection pattern CP may be connected to the first terminal ET1 of the transistor T SP while penetrating the first passivation layer PSV1.

A second passivation layer PSV2 may be disposed on the connection pattern CP and the first passivation layer PSV1. The second passivation layer PSV2 may protect components disposed under the second passivation layer PSV2, and provide a flat top surface.

A first anode electrode AE1 and a cathode electrode CE may be disposed on the pixel circuit layer PCL. The first anode electrode AE1 may be electrically connected to the connection pattern CP through a contact hole penetrating the second passivation layer PSV. As such, the first anode electrode AE1 may be electrically connected to the transistor T_SP. The cathode electrode CE may be spaced apart from the first anode electrode AE1. A common voltage may be applied to the cathode electrode CE.

A first bank BNK1 may be disposed on the first anode electrode AE1 and the cathode electrode CE. The first bank BNK1 may have a first opening OP1 exposing portions of the first anode electrode AE1 and the cathode electrode CE. The first bank BNK1 may be provided as a pixel defining layer defining an area in which a first light emitting element LD1 is located.

The first bank BNK1 may be configured to include a light blocking material, to prevent light mixture between adjacent sub-pixels. In embodiments, the first bank BNK1 may include an organic insulating material. For example, the first bank BNK1 may include acrylic resin, epoxy resin, phenolic resin, polyamide resin, and/or polyimide resin.

A first reflective electrode RFE1 may be disposed on the exposed portion of the first anode electrode AE1 and a side surface of the first bank BNK1, which is adjacent thereto. A second reflective electrode RFE2 may be disposed on the exposed portion of the cathode electrode CE and a side surface of the first bank BNK1, which is adjacent thereto. The first and second reflective electrodes RFE1 and RFE2 may include a conductive material suitable for reflecting light. Accordingly, the first and second reflective electrodes RFE1 and RFE2 may function to improve the light emission efficiency of light emitted from the first light emitting element LD1. The first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the first and second reflective electrodes RFE1 and RFE2 and the second passivation layer PSV2, an overcoat layer OCL may be disposed in the first opening OP1 of the first bank BNK1. The overcoat layer OCL may function to fix the first light emitting element LD1 not to move. In some embodiments, the overcoat layer OCL may include an adhesive (or cohesive) material. Also, the overcoat layer OCL may function to protect components disposed under the overcoat layer OCL from a foreign matter such as dust or moisture.

The first light emitting element LD1 may be attached to the overcoat layer OCL in the first opening OP1. In embodiments, the first light emitting element LD1 may be partially buried in the overcoat layer OCL. In other embodiments, the overcoat layer OCL may be partially provided in only an area adjacent to a lower portion of the first light emitting element LD1, and accordingly, the first light emitting element LD1 may not be partially buried in the overcoat layer OCL.

The first light emitting element LD1 may include a light emitting stack structure EST, a first bonding electrode BDE1, a second bonding electrode BDE2, and an insulative film 15.

The light emitting stack structure EST may include a first semiconductor layer 11, a second semiconductor layer 12 disposed under the first semiconductor layer 11, and an active layer 13 between the first semiconductor layer 11 and the second semiconductor layer 12. In embodiments, the light emitting stack structure EST may further include an auxiliary layer 14 disposed below the second semiconductor layer 12.

The first semiconductor layer 11 may provide holes to the active layer 13. The first semiconductor layer 11 may include at least one p-type semiconductor layer. For example, the first semiconductor layer 11 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a p-type dopant such as magnesium (Mg), zinc (Zn), calcium (Ca), strontium (Sr) or barium (Ba). However, the material constituting the first semiconductor layer 11 is not limited thereto. In addition, various materials may constitute the first semiconductor layer 11. In an embodiment, the first semiconductor layer 11 may include a gallium nitride (GaN) semiconductor material doped with the p-type dopant.

The second semiconductor layer 12 may be spaced apart from the first semiconductor layer 11. The second semiconductor layer 12 may provide electrons to the active layer 13. The second semiconductor layer 12 may include at least one n-type semiconductor layer. For example, the second semiconductor layer 13 may include at least one semiconductor material among gallium nitride (GaN), aluminum gallium nitride (AlGaN), indium gallium nitride (InGaN), aluminum nitride (AIN), and indium nitride (InN), and be an n-type semiconductor layer doped with an n-type dopant such as silicon (Si), germanium (Ge) or tin (Sn). However, the material constituting the second semiconductor layer 12 is not limited thereto. In addition, various materials may constitute the second semiconductor layer 12. In an embodiment, the second semiconductor layer 12 may include a gallium nitride (GaN) semiconductor material doped with the n-type dopant. In some embodiments, the second semiconductor layer 12 along with the auxiliary layer 14 may constitute an n-type semiconductor layer.

The active layer 13 may be between the first semiconductor layer 11 and the second semiconductor layer 12, and provide an area in which electrons and holes are recombined. As electrons and holes are recombined in the active layer 13, light may be generated, which has a level changed to a low energy level and has a wavelength corresponding to the low energy level. The active layer 13 may be formed in a single quantum well structure or a multi-quantum well structure. In case that the active layer 13 is formed in the multi-quantum well structure, a unit including a barrier layer, a strain reinforcing layer, and a well layer may be repeatedly stacked on each other, to form the active layer 13. However, embodiments of the active layer 13 are not limited thereto.

The auxiliary layer 14 may include a gallium nitride (GaN) semiconductor material which is substantially undoped with an impurity or is doped with the impurity in a relatively low concentration. The auxiliary layer 14 along with the second semiconductor layer 12 may constitute an n-type semiconductor layer.

The first bonding electrode BDE1 may be connected to the first semiconductor layer 11, and the second bonding electrode BDE2 may be connected to the second semiconductor layer 12. The first bonding electrode BDE1 may not be physically in contact with the second semiconductor layer 12, the active layer 13, and the second bonding electrode BDE2, and the second bonding electrode BDE2 may not be physically in contact with the first semiconductor layer 11 and the active layer 13. In embodiments, the first bonding electrode BDE1 and the second bonding electrode BDE2 may protrude in a same direction from the light emitting stack structure EST. For example, the first bonding electrode BDE1 and the second bonding electrode BDE2 may protrude in the third direction DR3.

The insulative film 15 may cover at least a portion of an outer circumferential surface of the light emitting stack structure EST. For example, the insulating film 15 may entirely cover the other surfaces except a bottom surface of the auxiliary layer 14. Also, the insulative film 15 may be configured to expose the first and second bonding electrodes BDE1 and BDE2 protruding from the light emitting stack structure EST. The insulative film 15 may function to prevent an electrical short circuit which may occur in case that the active layer 13 is in contact with another conductive material except the first and second semiconductor layers 11 and 12. In embodiments, the insulative film 15 may include a transparent insulating material.

A third passivation layer PSV3 may be disposed on the first and second reflective electrodes RFE1 and RFE2, the first light emitting element LD1, and the overcoat layer OCL. The third passivation layer PSV3 may protect components disposed under the third passivation layer PSV3, and provide a flat top surface. The third passivation layer PSV3 and at least one of the first and second passivation layers PSV1 and PSV2 may include a same material, but embodiments are not limited thereto.

The third passivation layer PSV3 may have second to fifth openings OP2, OP3, OP4, and OP5. The second opening OP2 may expose a top surface of the first bonding electrode BDE1. The third opening OP3 may expose a top surface of the second bonding electrode BDE2. The fourth opening OP4 may expose a top surface of the first reflective electrode RFE1. The fifth opening OP5 may expose a top surface of the second reflective electrode RFE2.

First and second transparent electrodes ITO1 and ITO2 may be disposed on the third passivation layer PSV3. The first transparent electrode ITO1 may electrically connect the first bonding electrode BDE1 exposed by the second opening OP2 to the first reflective electrode RFE1 exposed by the fourth opening OP4. The second transparent electrode ITO2 may electrically connect the second bonding electrode BDE2 exposed by the third opening OP3 to the second reflective electrode RFE2 exposed by the fifth opening OP5. Accordingly, the first bonding electrode BDE1 may be electrically connected to the first anode electrode AE1. The second bonding electrode BDE2 may be electrically connected to the cathode electrode through the second transparent electrode ITO2 and the second reflective electrode RFE2.

In embodiments, the first and second transparent electrodes ITO1 and ITO2 may be substantially transparent or translucent to satisfy a predetermined or selected light transmittance. For example, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

A capping layer CPL may be disposed over the third passivation layer PSV3. The capping layer CPL may function to protect components disposed under the capping layer CPL, such as the first and second transparent electrodes ITO1 and ITO2 and the first light emitting element LD1, from external moisture, humidity, and the like. The capping layer CPL may include, for example, silicon nitride, silicon oxide, silicon oxynitride, and/or aluminum oxide.

In the above, the pixel circuit layer PCL and the display panel layer DPL of the first sub-pixel SP1 have been described. Each of the second and third sub-pixels SP2 and SP3 shown in FIG. 6 may also be configured identically or similarly to the first sub-pixel SP1.

The light conversion layer LCL may be disposed on the capping layer CPL. The light conversion layer LCL may include a second bank BNK2, a reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap with the first bank BNK1. The second bank BNK2 may have a sixth opening OP6 overlapping with the first opening OP1.

The second bank BNK2 may be configured to include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the sixth opening OP6. The reflective layer RFL is configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 is disposed in the sixth opening OP6. The fourth passivation layer PSV4 may protect components disposed under the fourth passivation layer PSV4, and provide a flat surface. The fourth passivation layer PSV4 and at least one of the first to third passivation layers PSV1, PSV2, and PSV3 may include a same material, but embodiments are not limited thereto.

On the fourth passivation layer PSV4, the first light conversion pattern CCP1 may be disposed in the sixth opening OP6.

The first light conversion pattern CCP1 may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 configured to convert light of the blue color into light of a red color. In case that the first light emitting element LD1 emits light of the red color, the first light conversion pattern CCP1 may include light scattering particles. As such, the particles included in the first light conversion pattern CCP1 may be variously changed according to a color of light which the first light emitting element LD1 emits.

The low refractive layer LRL may be disposed on the second bank BNK2, the reflective layer RFL, and the first light conversion pattern CCP1. The low refractive layer LRL may have a refractive index lower than a refractive index of each of the first light conversion pattern CCP1 and a first color filter CF1. The low refractive layer LRL may be configured to refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include the first color filter CF1 and light blocking patterns LBP. The first color filter CF1 may overlap with the first light conversion pattern CCP1. The first color filter CF1 may allow light in a desired wavelength range to be selectively transmitted through the first color filter. In case that the first sub-pixel SP1 is a red sub-pixel, the first color filter CF1 may include a red color filter. The light blocking patterns LBP may include at least one of various kinds of light blocking materials.

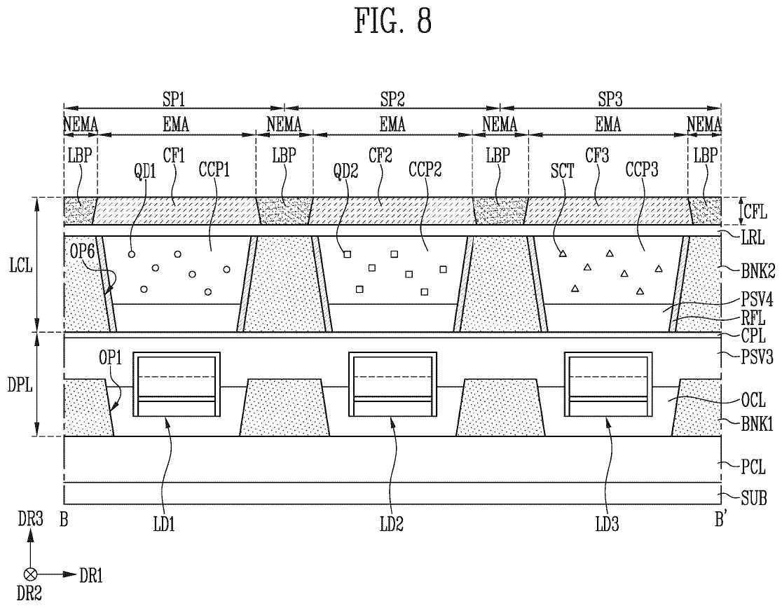

FIG. 8 is a schematic sectional view taken along line B-B′ shown in FIG. 6.

Referring to FIGS. 6 and 8, a pixel circuit layer PCL, a display panel layer DPL, and a light conversion layer LCL may be provided on a base substrate SUB.

The pixel circuit layer PCL and the display panel layer DPL may be the same as described with reference to FIG. 7. In the pixel circuit layer PCL, sub-pixel circuits respectively corresponding to the first to third sub-pixels SP1, SP2, and SP3 may be provided. In the display panel layer DPL, first to third light emitting elements LD1, LD2, and LD3 respectively corresponding to the first to third sub-pixels SP1, SP2, and SP3 may be provided. The first to third light emitting elements LD1, LD2, and LD3 may overlap with first openings OP1 of a first bank BNK1. The first light emitting element LD1 may be connected between a cathode electrode CE and a transistor T_SP included in a sub-pixel circuit of the first sub-pixel SP1. The second light emitting element LD2 may be connected between a cathode electrode CE and a transistor included in a sub-pixel circuit of the second sub-pixel SP2. The third light emitting element LD3 may be connected between the cathode electrode and a transistor included in a sub-pixel circuit of the third sub-pixel SP3. Hereinafter, redundant description will be omitted.

The light conversion layer LCL may be provided on the display panel layer DPL. The light conversion layer LCL may be the same as described with reference to FIG. 7. Hereinafter, descriptions of overlapping portions will be omitted.

A second bank BNK2 may have sixth openings OP6. It can be seen that emission areas EMA and a non-emission area NEMA of the first to third sub-pixels SP1, SP2, and SP3 may be defined as the second bank BNK2. An area overlapping with the second bank BNK2 may be the non-emission area NEMA. Areas overlapping with the sixth openings OP6 of the second bank BNK2 may be the emission areas EMA of the first to third sub-pixels SP1, SP2, and SP3.

On a capping layer CPL, a fourth passivation layer PSV4 may be disposed in the sixth openings OP6. On the fourth passivation layer PSV4, first to third light conversion patterns CCP1, CCP2, and CCP3 may be disposed in the sixth openings OP6.

In embodiments, the first to third light emitting elements LD1, LD2, and LD3 may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The third light conversion pattern CCP3 may include light scattering particles SCT which scatter light of the blue color so as to improve light emission efficiency. Accordingly, the first to third sub-pixels SP1, SP2, and SP3 may be provided as a red sub-pixel, a green sub-pixel, and a blue sub-pixel, respectively. In embodiments, at least one of the first to third light conversion patterns CCP1, CCP2, and CCP3 may further include color conversion particles configured to convert light of the blue color into light of a white color.

In embodiments, the first to third light emitting elements LD1, LD2, and LD3 may be configured to emit lights of the red color, the green color, and the blue color, respectively. Each of the first to third light conversion patterns CCP1, CCP2, and CCP3 may include light scattering particles SCT. As such, the particles included in the first to third light conversion patterns CCP1, CCP2, and CCP3 may be variously changed according to the first to third light emitting elements LD1, LD2, and LD3.

In some embodiments, the first to third light conversion patterns CCP1, CCP2, and CCP3 may be omitted.

A low refractive layer LRL may be disposed on the second bank BNK2, a reflective layer RFL, and the first to third light conversion patterns CCP1, CCP2, and CCP3. The low refractive layer LRL may have a refractive index lower than a refractive index of each of the first to third light conversion patterns CCP1, CCP2, and CCP3 and first to third color filters CF1, CF2, and CF3. In embodiments, the low refractive layer LRL may be omitted in an area corresponding to the third sub-pixel SP3.

A color filter layer CFL may be disposed on the low refractive layer LRL. The color filter layer CFL may include the first to third color filters CF1, CF2, and CF3 and light blocking patterns LBP.

Each of the first to third color filters CF1, CF2, and CF3 may allow light in a desired wavelength range to be selectively transmitted through the first to third color filters. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter.

The light blocking patterns LBP may be disposed between the color filters CF1, CF2, and CF3. It can be seen that the emission areas (or light emission areas) EMA and the non-emission area NEMA of the first to third sub-pixels SP1, SP2, and SP3 may be defined by the light blocking patterns LBP. Areas corresponding to the light blocking patterns LBP may correspond to the non-emission area NEMA. Areas not overlapping with the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping with at least two color filters among the first to third color filters CF1, CF2, and CF3. For example, each of the light blocking patterns LBP may be formed as the first to third color filters CF1, CF2, and CF3 overlapping with each other. In another example, a light blocking pattern between the first and second color filters CF1 and CF2 among the light blocking patterns LBP may be formed as a multi-layer in which the first and second color filters CF1 and CF2 overlap, and a light blocking pattern between the second and third color filters CF2 and CF3 among the light blocking patterns LBP may be formed as a multi-layer in which the second and third color filters CF2 and CF3 overlap. A light blocking pattern between the first color filter CF1 and a third color filter CF3 of an adjacent pixel may be formed as a multi-layer in which the first and third color filters CF1 and CF3 overlap. As such, each of the first to third color filters CF1 to CF3 may extend to the non-emission area NEMA to form the light blocking patterns LBP.

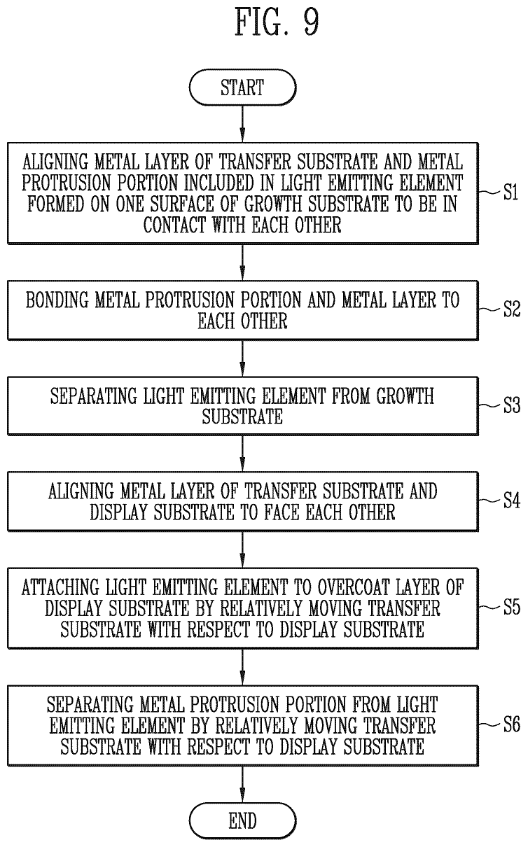

FIG. 9 is a schematic view illustrating a method of manufacturing the display device in accordance with an embodiment of the disclosure.

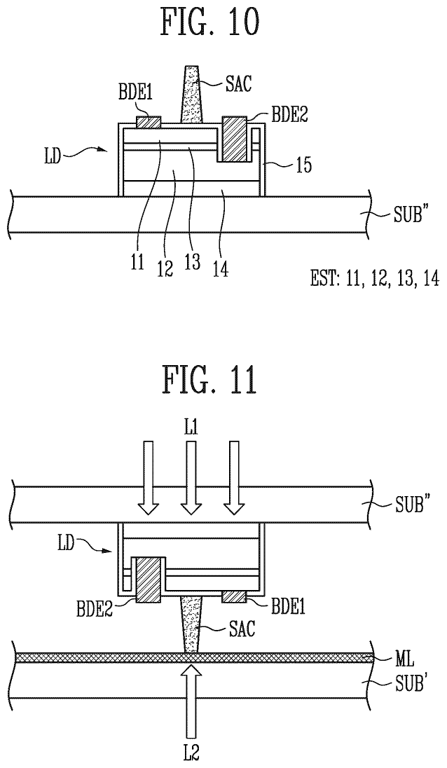

Referring to FIG. 9, the method of manufacturing the display device in accordance with the embodiment of the disclosure may include first to sixth steps S1, S2, S3, S4, S5, and S6. Hereinafter, the first to sixth steps S1, S2, S3, S4, S5, and S6 will be described with reference to FIGS. 10 to 16.

FIGS. 10 to 16 are schematic views illustrating the method shown in FIG. 9.

Referring to FIG. 10, before the first step S1, a growth substrate SUB″ and a light emitting element LD formed on a surface of the growth substrate SUB″ may be provided.

The growth substrate SUB″ may be a substrate for forming the light emitting element LD. For example, the growth substrate SUB″ may be a silicon wafer substrate.

The light emitting element LD may include a light emitting stack structure EST, a first bonding electrode BDE1, a second bonding electrode BDE2, an insulative film 15, and a metal protrusion portion SAC.

The light emitting stack structure EST may include a first semiconductor layer 11, a second semiconductor layer 12, and an active layer 13. In some embodiments, the light emitting stack structure EST may further include an auxiliary layer 14. The auxiliary layer 14, the second semiconductor layer 12, the active layer 13, and the first semiconductor layer 11 may be stacked on each other along a direction becoming distant from the growth substrate SUB″. The first semiconductor layer 11, the second semiconductor layer 12, the active layer 13, and the auxiliary layer 14 may be substantially identical or similar to the first semiconductor layer 11, the second semiconductor layer 12, the active layer 13, and the auxiliary layer 14, which have been described with reference to FIG. 7. Therefore, redundant description will be omitted.

The first bonding electrode BDE1 may be connected to the first semiconductor layer 11, and the second bonding electrode BDE2 may be connected to the second semiconductor layer 12. The first bonding electrode BDE1 may not be physically in contact with the second semiconductor layer 12, the active layer 13, and the second bonding electrode BDE2, and the second bonding electrode BDE2 may not be physically in contact with the first semiconductor layer 11 and the active layer 13. In embodiments, the first bonding electrode BDE1 and the second bonding electrode BDE2 may protrude in a same direction from the light emitting stack structure EST. For example, the first bonding electrode BDE1 and the second bonding electrode BDE2 may protrude in the direction becoming distant from the growth substrate SUB″.

The insulative film 15 may cover at least a portion of an outer circumferential surface of the light emitting stack structure EST. For example, the insulative film 15 may entirely cover the other surfaces except a surface in contact with the growth substrate SUB″, a surface connected to the first bonding electrode BDE1, and a surface connected to the second bonding electrode BDE2 in the outer circumferential of the light emitting stack structure EST. Also, the insulative film 15 may be configured to expose the first and second bonding electrodes BDE1 and BDE2 protruding from the light emitting stack structure EST. The insulative film 15 may function to prevent an electrical short circuit which may occur as the active layer 13 is in contact with another conductive material except the first and second semiconductor layers 11 and 12. In embodiments, the insulative film 15 may include a transparent insulating material.

The metal protrusion portion SAC may be disposed on the insulative film 15 covering a surface of the light emitting stack structure EST. The metal protrusion portion SAC may protrude from the surface of the light emitting stack structure EST in the direction becoming distant from the growth substrate SUB″. In embodiments, the metal protrusion portion SAC may include various kinds of metal materials and/or alloys of at least two metal materials selected therefrom.

The metal protrusion portion SAC may protrude in a same direction as the first and second bonding electrodes BDE1 and BDE2. In other words, each of the first bonding electrode BDE1 and the second bonding electrode BDE2 may protrude in a direction in which the metal protrusion portion SAC protrudes from the surface of the light emitting stack structure EST. In embodiments, with respect to the direction in which the metal protrusion portion SAC protrudes, the metal protrusion portion SAC may protrude further than the first and second bonding electrodes BDE1 and BDE2.

The metal protrusion portion SAC may not be physically in contact with the first and second bonding electrodes BDE1 and BDE2. That is, each of the first and second bonding electrodes BDE1 and BDE2 may be spaced apart from the metal protrusion portion SAC.

In embodiments, the method of forming the growth substrate SUB″ and the light emitting element LD formed on the surface of the growth substrate SUB″ is not limited. For example, various semiconductor manufacturing methods, such as growing of an epitaxial layer on a silicon wafer, may be applied without limitation.

For convenience of description, only one light emitting element LD is illustrated in FIG. 10. However, embodiments are not limited thereto. For example, multiple light emitting elements LD may be provided on the surface of the growth substrate SUB″, and portions described with reference to FIGS. 11 to 16 may be substantially equally or similarly applied to the multiple light emitting elements. Hereinafter, only one light emitting element LD will be illustrated even in FIGS. 11 to 16. The light emitting element LD shown in FIGS. 10 to 16 may correspond to any one of the first to third light emitting elements LD1, LD2, and LD3 which have been described with reference to FIGS. 6 to 8.

Referring to FIG. 11, a transfer substrate SUB′ may be provided. The transfer substrate SUB′ may be a substrate for transferring the light emitting element LD. In embodiments, a metal layer ML may be disposed on a surface of the transfer substrate SUB′. The metal layer ML may include various kinds of metal materials and/or alloys of at least two metal materials selected therefrom.

The transfer substrate SUB′ and the growth substrate SUB″ may be aligned with each other (S1). Accordingly, the metal layer ML of the transistor substrate SUB′ and the metal protrusion portion SAC included in the light emitting element LD formed on the surface of the growth substrate SUB″ may be in contact with each other. The first and second bonding electrodes BDE1 and BDE2 of the light emitting element LD may protrude less than the metal protrusion portion SAC. Accordingly, the first and second bonding electrodes BDE1 and BDE2 may be spaced apart from the metal layer ML, and the contact reliability of the metal protrusion portion SAC and the metal layer ML can be ensured.

The metal protrusion portion SAC and the metal layer ML may be bonded to each other (S2). This may be performed by applying sufficient heat to an area in which the metal protrusion portion SAC and the metal layer ML are in contact with each other. For example, second laser L2 may be irradiated onto the area in which the metal protrusion portion SAC and the metal layer ML are in contact with each other. The metal protrusion portion SAC and the metal layer ML may form an alloy in the area in which the metal protrusion portion SAC and the metal layer ML are in contact with each other, so that the metal protrusion portion SAC and the metal layer ML can be bonded to each other.

The light emitting element LD may be separated from the growth substrate SUB″ (S3). This may be performed by irradiating first laser L1 onto an area in which the growth substrate SUB″ and the light emitting element LD are in contact with each other.

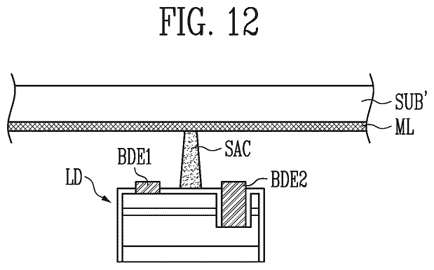

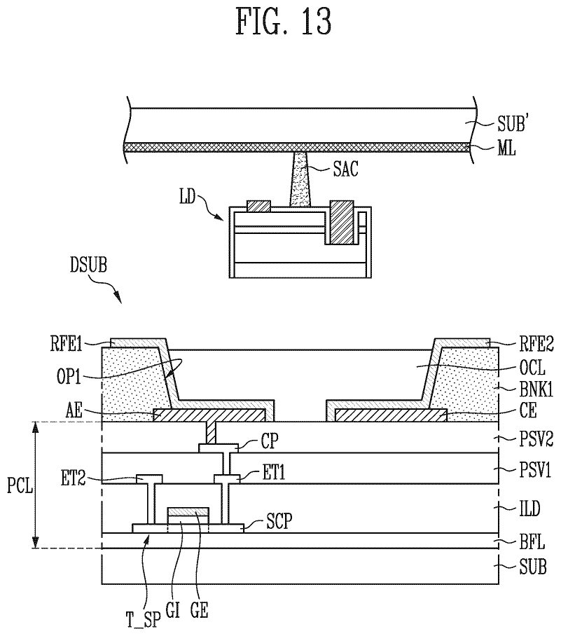

Referring to FIG. 12, after the first to third steps S1, S2, and S3 which have been described with reference to FIG. 11 are performed, the light emitting element LD may be bonded and fixed to the metal layer ML through the metal protrusion portion SAC. That is, metal-metal bonding between the metal protrusion portion SAC and the metal layer ML may be used to fix the light emitting element LD to the transfer substrate SUB′. Accordingly, the light emitting element LD can be more effectively fixed to the transfer substrate SUB′.

In the disclosure, the light emitting element LD may be bonded and fixed to the metal layer ML through the metal protrusion portion SAC. That is, metal-metal bonding between the metal protrusion portion SAC and the metal layer ML may be used to fix the light emitting element LD to the transfer substrate SUB′. Accordingly, the light emitting element LD can be more effectively fixed to the transfer substrate SUB′.

In addition, the transfer substrate SUB′ may include the metal layer ML in which an alignment mark (e.g., a mark having a specific shape, which is formed in the metal layer ML to facilitate identification thereof) is readily formed, and thus the reliability of alignment in an alignment step (S4) which will be described later can be readily ensured. Referring to FIG. 13, the light emitting element LD fixed to the transfer substrate SUB′ may be transferred, thereby aligning the metal layer ML of the transfer substrate SUB′ and a display substrate DSUB to face each other (S4). The light emitting element LD may be aligned to be located on an overcoat layer OCL of the display substrate DSUB, using the above-described alignment mark, or the like.

The display substrate DSUB may include a base substrate SUB and various components disposed on the base substrate SUB. The base substrate SUB may be made of an insulative material such as glass or resin. For example, the base substrate SUB may include a glass substrate. In another example, the base substrate SUB may include a polyimide (PI) substrate.

Various components for providing various signals (or voltages) to the light emitting element LD or improving the light emission efficiency and reliability of the light emitting element LD may be disposed on the base substrate SUB. For example, a pixel circuit layer PCL, an anode electrode AE, a cathode electrode CE, a first bank BNK1, a first reflective electrode RFE1, a second reflective electrode RFE2, and the overcoat layer OCL may be disposed on the base substrate SUB. The pixel circuit layer PCL, the anode electrode AE, the cathode electrode CE, the first bank BNK1, the first reflective electrode RFE1, the second reflective electrode RFE2, and the overcoat layer OCL may be substantially identical or similar to the pixel circuit layer PCL, the first anode electrode AE1, the cathode electrode CE, the first bank BNK1, the first reflective electrode RFE1, the second reflective electrode RFE2, and the overcoat layer OCL, which have been described with reference to FIGS. 7 and 8. Therefore, redundant description will be omitted.

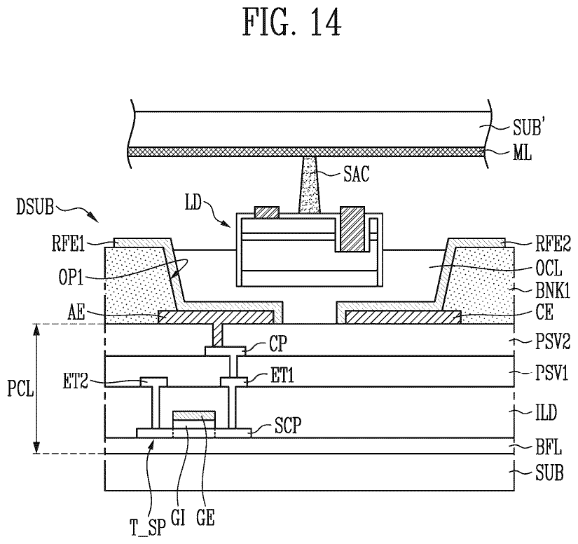

Referring to FIG. 14, the light emitting element LD may be attached to the overcoat layer OCL by moving the transfer substrate SUB′ relative to the display substrate DSUB (S5). For example, the transfer substrate SUB′ may be moved in a direction toward the display substrate DSUB, and accordingly, the light emitting element LD may be partially buried in the overcoat layer OCL. In some embodiments, the overcoat layer OCL may be partially provided in only an area adjacent to a lower portion of the light emitting element LD, and accordingly, the light emitting element LD may not be partially buried in the overcoat layer OCL.

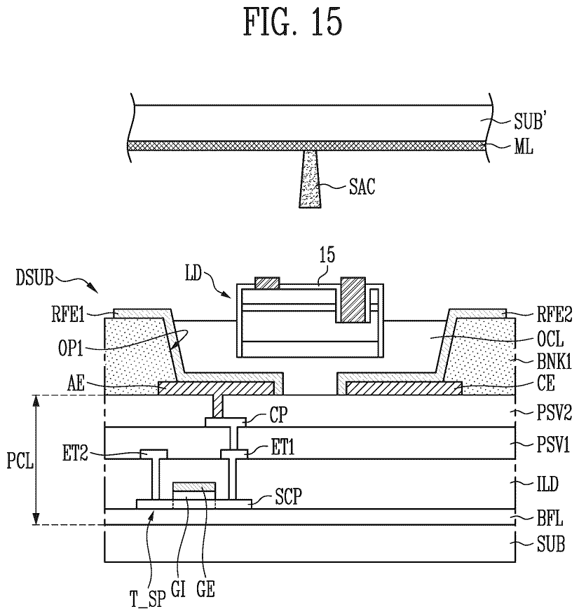

Referring to FIG. 15, the metal protrusion portion SAC may be separated from the light emitting element LD by moving the transfer substrate SUB′ relative to the display substrate DSUB (S6). For example, the transfer substrate SUB′ may be moved in a direction becoming distant from the display substrate DSUB.

The bonding between the metal protrusion portion SAC and the metal layer ML may be maintained. That is, in case that the sixth step S6 is performed, the metal protrusion portion SAC and the metal layer ML may be in a state in which the metal protrusion portion SAC and the metal layer ML are bonded to each other. In addition, the attachment between the light emitting element LD and the overcoat layer OCL may be maintained. That is, in case that the sixth step S6 is performed, the light emitting element LD may maintain a position substantially equal to the position at which the light emitting element LD has been attached to the overcoat layer OCL in the fifth step S5.

In an embodiment, a bonding force between the metal protrusion portion SAC and the insulative film 15 may be weaker than an adhesive force between the light emitting element LD and the overcoat layer OCL. The metal protrusion portion SAC can be effectively separated from the light emitting element LD in case that the sixth step S6 is performed. Further, the attachment between the light emitting element LD and the overcoat layer OCL can be effectively maintained.

In an embodiment, the bonding force between the metal protrusion portion SAC and the insulative film 15 may be weaker than a bonding force between the metal protrusion portion SAC and the metal layer ML. The bonding between the metal protrusion portion SAC and the metal layer ML can be effectively maintained in case that the sixth step S6 is performed, and thus the protrusion portion SAC can be effectively separated from the light emitting element LD.

In an embodiment, the bonding force between the metal protrusion portion SAC and the metal layer ML may be weaker than the adhesive force between the light emitting element LD and the overcoat layer OCL. In case that the sixth step S6 is performed, the light emitting element LD may maintain a position substantially equal to the position at which the light emitting element LD has been attached to the overcoat layer OCL in the fifth step S5.

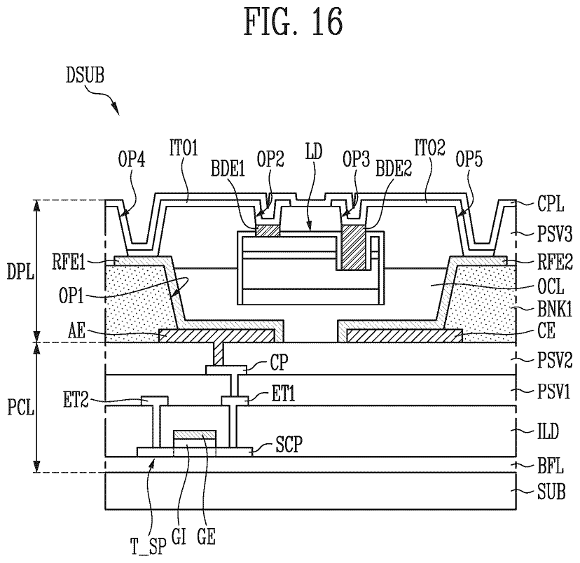

Referring to FIG. 16, various components for connecting the light emitting element LD to the anode electrode AE and the cathode electrode CE may be further formed after the sixth step S6 is performed. For example, a third passivation layer PSV3, first and second transparent electrodes ITO1 and ITO2, and a capping layer CPL may be further formed. The third passivation layer PSV3, the first and second transparent electrodes ITO1 and ITO2, and the capping layer CPL may be substantially identical or similar to the third passivation layer PSV3, the first and second transparent electrodes ITO1 and ITO2, and the capping layer CPL, which have been described with reference to FIGS. 7 and 8. Therefore, redundant description will be omitted.

A display substrate DSUB including the base substrate SUB, the pixel circuit layer PCL, and a display panel layer DPL may be formed. Although not shown in FIG. 16, the light conversion layer LCL which has been described with reference to FIGS. 7 and 8 may be further formed on the display panel layer DPL.

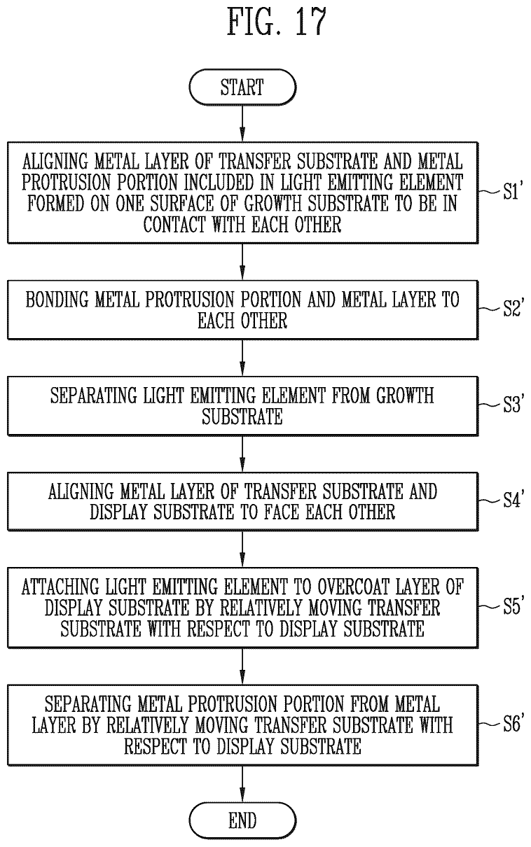

FIG. 17 is a schematic view illustrating a method of manufacturing the display device in accordance with another embodiment of the disclosure.

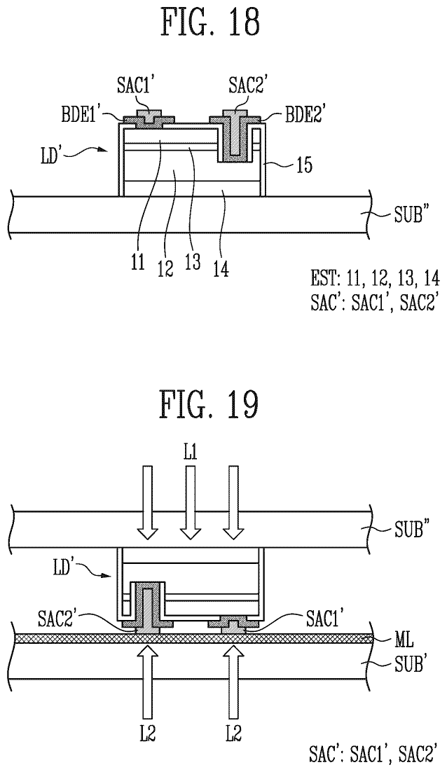

Referring to FIG. 17, the method of manufacturing the display device in accordance with another embodiment of the disclosure may include first to sixth steps S1′, S2′, S3′, S4′, S5′, and S6′. Hereinafter, the first to sixth steps S1′, S2′, S3′, S4′, S5′, and S6′ will be described with reference to FIGS. 18 to 24.

FIGS. 18 to 24 are schematic views illustrating the method shown in FIG. 17.

Referring to FIG. 18, before the first step S1′, a growth substrate SUB″ and a light emitting element LD′ formed on a surface of the growth substrate SUB″ may be provided.

The growth substrate SUB″ may be a substrate for forming the light emitting element LD′. For example, the growth substrate SUB″ may be a silicon wafer substrate.

The light emitting element LD′ may include a light emitting stack structure EST, a first bonding electrode BDE1′, a second bonding electrode BDE2′, an insulative film 15, and a metal protrusion portion SAC′.

The light emitting stack structure EST may be substantially identical or similar to the light emitting stack structure EST which has been described with reference to FIG. 10. The light emitting stack structure EST may include a first semiconductor layer 11, a second semiconductor layer 12, and an active layer 13. In some embodiments, the light emitting stack structure EST may further include an auxiliary layer 14. Hereinafter, redundant description will be omitted.

The first bonding electrode BDE1′ may be connected to the first semiconductor layer 11, and the second bonding electrode BDE2′ may be connected to the second semiconductor layer 12. The first bonding electrode BDE1′ may not be physically in contact with the second semiconductor layer 12, the active layer 13, and the second bonding electrode BDE2′, and the second bonding electrode BDE2′ may not be physically in contact with the first semiconductor layer 11 and the active layer 13. In embodiments, the first bonding electrode BDE1′ and the second bonding electrode BDE2′ may protrude in a same direction from the light emitting stack structure EST. For example, the first bonding electrode BDE1′ and the second bonding electrode BDE2′ may protrude in the direction becoming distant from the growth substrate SUB″.

The insulative film 15 may cover at least a portion of an outer circumferential surface of the light emitting stack structure EST. For example, the insulative film 15 may entirely cover the other surfaces except a surface in contact with the growth substrate SUB″, a surface connected to the first bonding electrode BDE1′, and a surface connected to the second bonding electrode BDE2′ in the outer circumferential of the light emitting stack structure EST. The insulative film 15 may be configured to expose the first and second bonding electrodes BDE1′ and BDE2′ protruding from the light emitting stack structure EST. The insulative film 15 may function to prevent an electrical short circuit which may occur as the active layer 13 is in contact with another conductive material except the first and second semiconductor layers 11 and 12. In embodiments, the insulative film 15 may include a transparent insulating material.

The metal protrusion portion SAC′ may include at least one of a first metal protrusion portion SAC1′ overlapping with the first bonding electrode BDE1′ and a second metal protrusion portion SAC2′ overlapping with the second bonding electrode BDE2′. For example, as shown in FIG. 18, the metal protrusion portion SAC′ may include the first metal protrusion portion SAC1′ and the second metal protrusion portion SAC2′.

The first metal protrusion portion SAC1′ may be disposed on the first bonding electrode BDE1′. The second metal protrusion portion SAC2′ may be disposed on the second bonding electrode BDE2′. In embodiments, the first metal protrusion portion SAC1′ may be in direct contact with the first bonding electrode BDE1′, and the second metal protrusion portion SAC2′ may be in direct contact with the second bonding electrode BDE2′. In embodiments, the first and second metal protrusion portions SAC1′ and SAC2′ may include various kinds of metal materials and/or alloys of at least two metal materials selected therefrom.

The first and second metal protrusion portions SAC1′ and SAC2′ may protrude in a direction becoming distant from the growth substrate SUB″. The first and second metal protrusion portions SAC1′ and SAC2′ may protrude further than the first and second bonding electrodes BDE1′ and BDE2′. An uppermost surface of the first metal protrusion portion SAC1′ and an uppermost surface of the second metal protrusion portion SAC2′ may be located at a same height.

In embodiments, the method of forming the growth substrate SUB″ and the light emitting element LD′ formed on the surface of the growth substrate SUB″ is not limited. For example, various semiconductor manufacturing methods, such as growing of an epitaxial layer on a silicon wafer, may be applied without limitation.

For convenience of description, only one light emitting element LD′ is illustrated in FIG. 18. However, embodiments are not limited thereto. For example, multiple light emitting elements LD′ may be provided on the surface of the growth substrate SUB″, and portions described with reference to FIGS. 19 to 24 may be substantially equally or similarly applied to the multiple light emitting elements. Hereinafter, only one light emitting element LD will be illustrated even in FIGS. 19 to 24. The light emitting element LD′ shown in FIGS. 18 to 24 may correspond to any one of the first to third light emitting elements LD1, LD2, and LD3 which have been described with reference to FIGS. 6 to 8.

Referring to FIG. 19, a transfer substrate SUB′ may be provided. The transfer substrate SUB′ may be a substrate for transferring the light emitting element LD′. In embodiments, a metal layer ML may be disposed on a surface of the transfer substrate SUB′. The metal layer ML may include various kinds of metal materials and/or alloys of at least two metal materials selected therefrom.

The transfer substrate SUB′ and the growth substrate SUB″ may be aligned with each other (S1′). Accordingly, the metal layer ML of the transistor substrate SUB′ and the metal protrusion portion SAC′ included in the light emitting element LD′ formed on the surface of the growth substrate SUB″ may be in contact with each other.

The metal protrusion portion SAC′ and the metal layer ML may be bonded to each other (S2′). This may be performed by applying sufficient heat to an area in which the metal protrusion portion SAC′ and the metal layer ML are in contact with each other. For example, second laser L2 may be irradiated onto the area in which the metal protrusion portion SAC′ and the metal layer ML are in contact with each other. The metal layer ML and the metal protrusion portion SAC′ may form an alloy in the area in which the metal protrusion portion SAC′ and the metal layer ML are in contact with each other, so that the metal protrusion portion SAC′ and the metal layer ML can be bonded to each other.

The light emitting element LD′ may be separated from the growth substrate SUB″ (S3′). This may be performed by irradiating first laser L1 onto an area in which the growth substrate SUB″ and the light emitting element LD′ are in contact with each other.

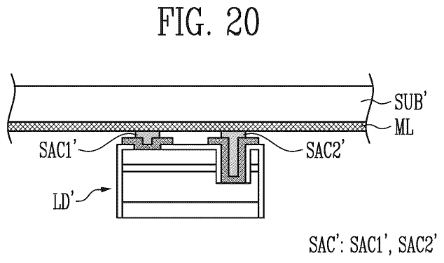

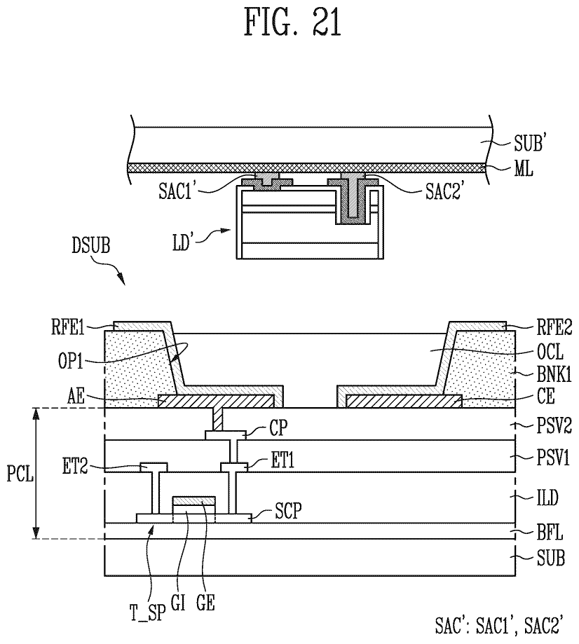

Referring to FIG. 20, after the first to third steps S1′, S2′, and S3′ which have been described with reference to FIG. 19 are performed, the metal protrusion portion SAC′ of the light emitting element LD may be bonded to the metal layer ML. Accordingly, the light emitting element LD′ may be fixed to the transfer substrate SUB′, and the light emitting element LD′ fixed to the transfer substrate SUB′ may be transferred.

Referring to FIG. 21, the light emitting element LD′ fixed to the transfer substrate SUB′ may be transferred, thereby aligning the metal layer ML of the transfer substrate SUB′ and a display substrate DSUB to face each other (S4′). The light emitting element LD1′ may be aligned to be located on the overcoat layer OCL of the display substrate DSUB.

The display substrate DSUB may be substantially identical or similar to the display substrate DSUB which has been described with reference to FIG. 13. Therefore, redundant description will be omitted.

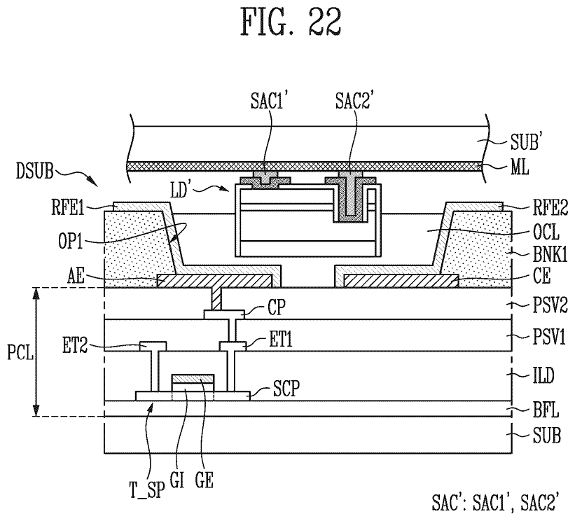

Referring to FIG. 22, the light emitting element LD′ may be attached to the overcoat layer OCL by moving the transfer substrate SUB′ relative to the display substrate DSUB (S5′). For example, the transfer substrate SUB′ may be moved in a direction toward the display substrate DSUB, and accordingly, the light emitting element LD′ may be partially buried in the overcoat layer OCL. In some embodiments, the overcoat layer OCL may be partially provided in only area adjacent to a lower portion of the light emitting element LD′, and accordingly, the light emitting element LD′ may not be partially buried in the overcoat layer OCL.

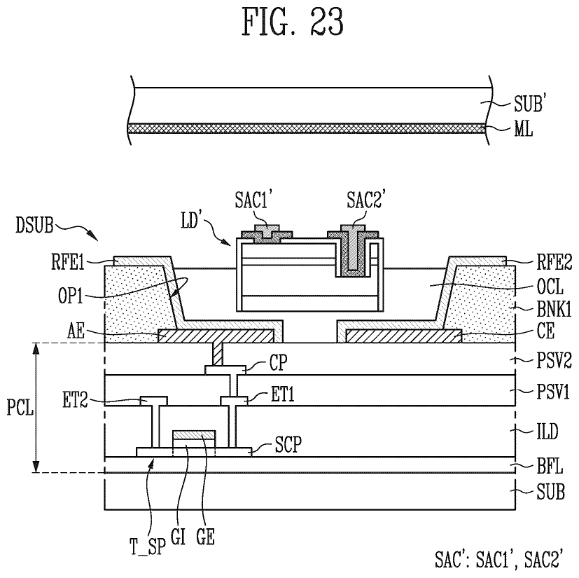

Referring to FIG. 23, the metal protrusion portion SAC′ of the light emitting element LD′ may be separated from the metal layer ML by moving the transfer substrate SUB′ relative to the display substrate DSUB (S6′). For example, the transfer substrate SUB′ may be moved in a direction becoming distant from the display substrate DSUB.

The attachment between the light emitting element LD′ and the overcoat layer OCL may be maintained. That is, in case that the sixth step S6′ is performed, the light emitting element LD′ may maintain a position substantially equal to the position at which the light emitting element LD′ has been attached to the overcoat layer OCL in the fifth step S5′.

In an embodiment, a bonding force between the metal protrusion portion SAC′ and the metal layer ML may be weaker than an adhesive force between the light emitting element LD′ and the overcoat layer OCL. The metal protrusion portion SAC′ can be effectively separated from the metal layer ML in case that the sixth step S6′ is performed. Further, the attachment between the light emitting element LD′ and the overcoat layer OCL can be effectively maintained.

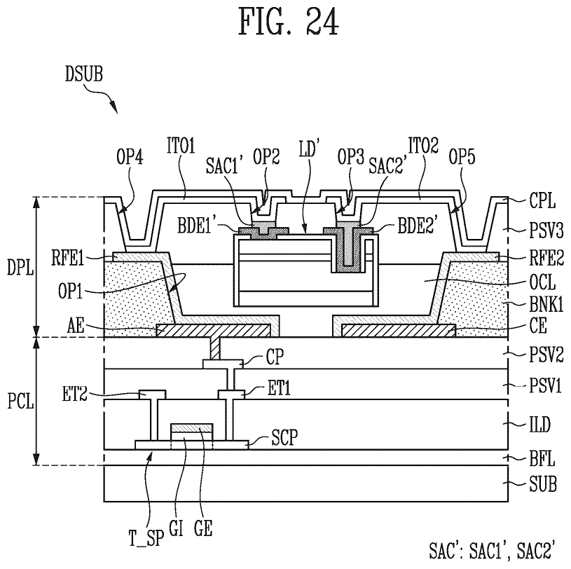

Referring to FIG. 24, various components for connecting the light emitting element LD′ to the anode electrode AE and the cathode electrode CE may be further formed after the sixth step S6′ is performed. For example, a third passivation layer PSV3, first and second transparent electrodes ITO1 and ITO2, and a capping layer CPL may be further formed.

The third passivation layer PSV3 may be disposed on first and second reflective electrodes RFE1 and RFE2, the light emitting element LD, and the overcoat layer OCL. The third passivation layer PSV3 may protect components disposed under the third passivation layer PSV3, and provide a flat top surface. The third passivation layer PSV3 and at least one of first and second passivation layers PSV1 and PSV2 may include a same material, but embodiments are not limited thereto.

The third passivation layer PSV3 may have second to fifth openings OP2, OP3, OP4, and OP5. The second opening OP2 may expose a top surface of the first metal protrusion portion SAC1′. In some embodiments, in case that the first metal protrusion portion SAC1′ is omitted, the second opening OP2 may expose a top surface of the first bonding electrode BDE1′. The third opening OP3 may expose a top surface of the second metal protrusion portion SAC2′.

In some embodiments, in case that the second metal protrusion portion SAC2′ is omitted, the third opening OP3 may expose a top surface of the second bonding electrode BDE2′. The fourth opening OP4 may expose a top surface of the first reflective electrode RFE1. The fifth opening OP5 may expose a top surface of the second reflective electrode RFE2.

The first and second transparent electrodes ITO1 and ITO2 may be disposed on the third passivation layer PSV3. The first transparent electrode ITO1 may electrically connect the first metal protrusion portion SAC1′ exposed by the second opening OP2 to the first reflective electrode RFE1 exposed by the fourth opening OP4. The second transparent electrode ITO2 may electrically connect the second metal protrusion portion SAC2′ exposed by the third opening OP3 to the second reflective electrode RFE2 exposed by the fifth opening OP5. Accordingly, the first metal protrusion portion SAC1′ may be electrically connected to the anode electrode AE through the first transparent electrode ITO1 and the first reflective electrode RFE1. The second metal protrusion portion SAC2′ may be electrically connected to the cathode electrode CE through the second transparent electrode ITO2 and the second reflective electrode RFE2.

In embodiments, the first and second transparent electrodes ITO1 and ITO2 may be substantially transparent or translucent to satisfy a predetermined or selected light transmittance. For example, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The capping layer CPL may be disposed over the third passivation layer PSV3. The capping layer CPL may function to protect components disposed under the capping layer CPL, such as the first and second transparent electrodes ITO1 and ITO2 and the first light emitting element LD1′, from external moisture, humidity, and the like. The capping layer CPL may include, for example, silicon nitride, silicon oxide, silicon oxynitride, and/or aluminum oxide.

As such, the display substrate DSUB including the base substrate SUB, the pixel circuit layer PCL, and a display panel layer DPL may be formed. Although not shown in FIG. 24, the light conversion layer LCL which has been described with reference to FIGS. 7 and 8 may be further formed on the display panel layer DPL.

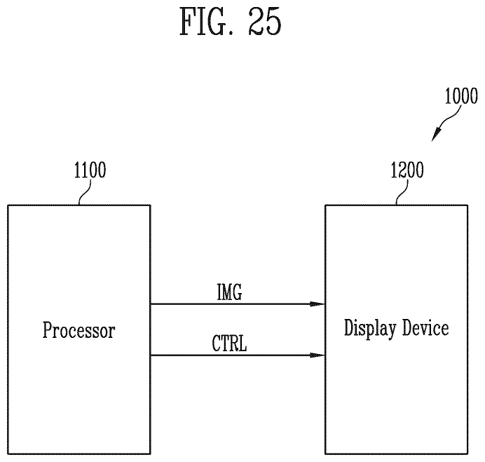

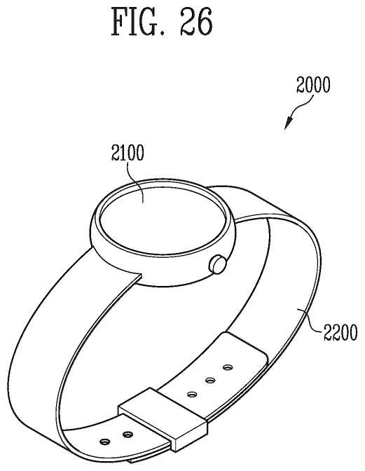

FIG. 25 is a schematic block diagram illustrating a display system in accordance with an embodiment of the disclosure.

Referring to FIG. 25, the display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identical or similar to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

FIGS. 26 to 29 are schematic perspective views illustrating application examples of the display system shown in FIG. 25.

Referring to FIG. 26, the display system 1000 shown in FIG. 25 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information can be provided to the user.

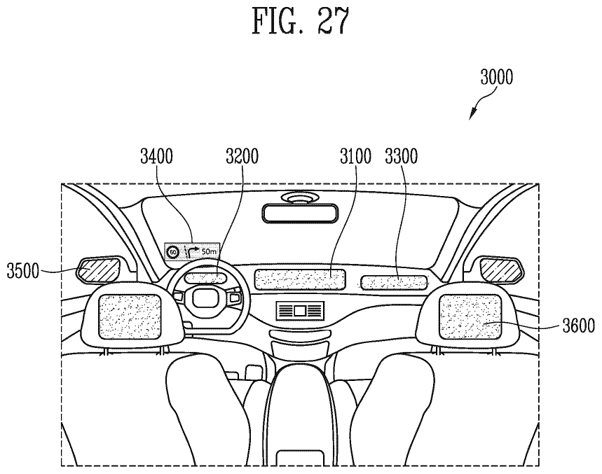

Referring to FIG. 27, the display system 1000 shown in FIG. 25 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a read seat display 3600, which are provided in the vehicle.

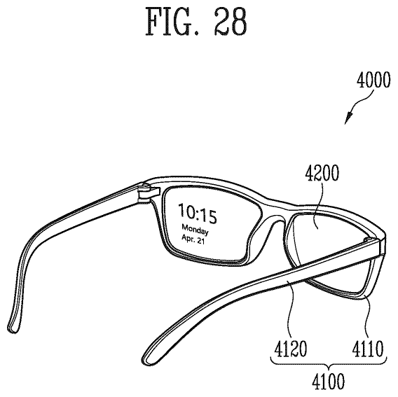

Referring to FIG. 28, the display system 1000 shown in FIG. 25 may be applied to smart glasses 4000. The smart glasses 4000 are a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. In addition, a projector for outputting light, a processor for controlling a light signal, and the like may be built in the frame 4100.

The lens part 4200 may be an optical member which allows light to be transmitted the lens part or allows light to be reflected thereby. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

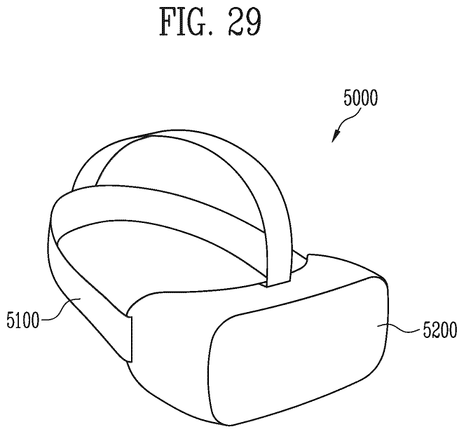

Referring to FIG. 29, the display system 1000 shown in FIG. 25 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In accordance with the disclosure, the method of manufacturing the display device may include a step of providing a light emitting element from a transfer substrate to a display substrate, using a metal layer of the transfer substrate and the light emitting element including a metal protrusion portion bonded to the metal layer. Accordingly, the reliability of the step of providing the light emitting element to the display substrate can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A method of manufacturing a display device, the method comprising:
aligning a metal layer of a transfer substrate and a display substrate to face each other;
attaching a light emitting element including a metal protrusion portion bonded to the metal layer to an overcoat layer of the display substrate by moving the transfer substrate relative to the display substrate; and
separating the metal protrusion portion from the light emitting element by moving the transfer substrate relative to the display substrate.

2. The method of claim 1, wherein, in the separating of the metal protrusion portion from the light emitting element, the bonding between the metal protrusion portion and the metal layer is maintained.

3. The method of claim 1, wherein, in the separating of the metal protrusion portion from the light emitting element, the attachment between the light emitting element and the overcoat layer is maintained.

4. The method of claim 1, wherein the light emitting element includes:
a light emitting stack structure including a first semiconductor layer, a second semiconductor layer spaced apart from the first semiconductor layer, and an active layer between the first semiconductor layer and the second semiconductor layer;
a first bonding electrode electrically connected to the first semiconductor layer;
a second bonding electrode electrically connected to the second semiconductor layer; and
an insulative film covering at least a portion of an outer circumferential surface of the light emitting stack structure.

5. The method of claim 4, wherein, before the separating of the metal protrusion portion from the light emitting element, the metal protrusion portion is in a state in which the metal protrusion portion is bonded to the insulative film covering a surface of the light emitting stack structure.

6. The method of claim 5, wherein each of the first bonding electrode and the second bonding electrode protrudes in a direction in which the metal protrusion portion protrudes from the surface of the light emitting stack structure.

7. The method of claim 6, wherein the metal protrusion portion protrudes further than the first and second bonding electrodes with respect to the direction in which the metal protrusion portion protrudes.

8. The method of claim 5, wherein a bonding force between the metal protrusion portion and the insulative film is weaker than an adhesive force between the light emitting element and the overcoat layer.

9. The method of claim 8, wherein the bonding force between the metal protrusion portion and the insulative film is weaker than a bonding force between the metal protrusion portion and the metal layer.

10. The method of claim 9, wherein the bonding force between the metal protrusion portion and the metal layer is weaker than the adhesive force between the light emitting element and the overcoat layer.

11. The method of claim 4, wherein each of the first bonding electrode and the second bonding electrode is spaced apart from the metal protrusion portion.

12. The method of claim 1, further comprising:
before the aligning of the metal layer of the transfer substrate and the display substrate to face each other:
aligning the metal layer of the transfer substrate and the metal protrusion portion included in the light emitting element formed on a surface of a growth substrate to physically contact each other;
bonding the metal protrusion portion and the metal layer to each other; and
separating the light emitting element from the growth substrate.

13. The method of claim 12, wherein the separating of the light emitting element from the growth substrate includes irradiating first laser onto an area in which the growth substrate and the light emitting element physically contact each other.

14. The method of claim 12, wherein the bonding of the metal protrusion portion and the metal layer to each other includes irradiating second laser onto an area in which the metal protrusion portion and the metal layer physically contact each other.

15. The method of claim 12, wherein the bonding of the metal protrusion portion and the metal layer to each other includes allowing the metal layer and the metal protrusion portion to form an alloy in an area in which the metal protrusion portion and the metal layer physically contact each other.

16. A method of manufacturing a display device, the method comprising:
aligning a metal layer of a transfer substrate and a display substrate to face each other;
attaching a light emitting element including a metal protrusion portion bonded to the metal layer to an overcoat layer of the display substrate by moving the transfer substrate relative to the display substrate; and
separating the metal protrusion portion from the metal layer by moving the transfer substrate relative to the display substrate, wherein
the light emitting element includes:
a light emitting stack structure including a first semiconductor layer, a second semiconductor layer spaced apart from the first semiconductor layer, and an active layer between the first semiconductor layer and the second semiconductor layer;
a first bonding electrode electrically connected to the first semiconductor layer; and
a second bonding electrode electrically connected to the second semiconductor layer, and
the metal protrusion portion includes at least one of a first metal protrusion portion overlapping the first bonding electrode and a second metal protrusion portion overlapping the second bonding electrode.

17. The method of claim 16, wherein, in the separating of the metal protrusion portion from the metal layer, the attachment between the light emitting element and the overcoat layer is maintained.

18. The method of claim 16, wherein a bonding force between the metal protrusion portion and the metal layer is weaker than an adhesive force between the light emitting element and the overcoat layer.

19. The method of claim 16, further comprising:
before the aligning of the metal layer of the transfer substrate and the display substrate to face each other:
aligning the metal layer of the transfer substrate and the metal protrusion portion included in the light emitting element formed on a surface of a growth substrate to physically contact each other;
bonding the metal protrusion portion and the metal layer to each other; and
separating the light emitting element from the growth substrate.

20. The method of claim 19, wherein the bonding of the metal protrusion portion and the metal layer to each other includes allowing the metal layer and the metal protrusion portion to form an alloy in an area in which the metal protrusion portion and the metal layer physically contact each other.
